(19) United States
(12) Patent Application Publication
(10) Pub. No.: US 2026/0304744 A1
(43) Pub. Date: Oct. 1, 2026

(54) SEMICONDUCTOR MEMORY DEVICE

(71) Applicant: Samsung Electronics Co., Ltd., Suwon-si (KR)

(72) Inventors: Donghyun Jang, Suwon-si (KR); Giduck Kweon, Suwon-si (KR); Dongchan Kim, Suwon-si (KR); Jin Sung Kim, Suwon-si (KR); Jisu Byun, Suwon-si (KR); Dongwook Seo, Suwon-si (KR); Dong Min Sim, Suwon-si (KR); Wonseok Yoo, Suwon-si (KR); Namhoon Lee, Suwon-si (KR)

(73) Assignee: Samsung Electronics Co., Ltd., Suwon-si (KR)

(21) Appl. No.: 19/374,654

(22) Filed: Oct. 30, 2025

(30) Foreign Application Priority Data
Apr. 1, 2025 (KR) 10-2025-0042209

(51) Int. Cl. H10B 12/00; H10D 30/01; H10D 30/63

(52) U.S. Cl. CPC H10B 12/315; H10B 12/09; H10B 12/482; H10B 12/50; H10D 30/025; H10D 30/63

(57) ABSTRACT

The present invention provides a semiconductor memory device. A semiconductor memory device includes a lower insulating layer, back-gate lines each extending in a first direction on the lower insulating layer, first semiconductor patterns on first side surfaces of the back-gate lines, and second semiconductor patterns on second side surfaces of the back gate lines. The first semiconductor patterns and the second semiconductor patterns are alternately disposed along the first direction.

### CROSS-REFERENCE TO RELATED APPLICATIONS

This present application claims priority to and the benefit under 35 U.S.C. § 119(a)-(d) of Korean Patent Application No. 10-2025-0042209, filed on Apr. 1, 2025 in the Korean Intellectual Property Office, the entire disclosure of which is incorporated herein by reference.

### FIELD

Embodiments of disclosed concepts relate to a semiconductor memory device, and more particularly, to a semiconductor memory device including vertical channel transistors and a method for manufacturing the same.

### BACKGROUND

With the trend of reduction in design rule of a semiconductor memory device, the fabrication technology is being improved to increase integration, operating speed, and yield of the semiconductor memory device. Accordingly, transistors with vertical channels have been suggested to increase their integration, resistance, current driving capability, and so forth.

### SUMMARY

Embodiments of disclosed concepts relate a semiconductor memory device with improved electrical characteristics and integration.

A semiconductor memory device according to some embodiments of the disclosed concepts may include a lower insulating layer, back-gate lines each extending in a first direction on the lower insulating layer, first semiconductor patterns on first side surfaces of the back-gate lines, and second semiconductor patterns on second side surfaces of the back-gate lines, wherein the first semiconductor patterns and the second semiconductor patterns are alternately disposed along the first direction.

A semiconductor memory device according to some embodiments of the disclosed concepts may include a lower insulating layer; a back-gate line extending in a first direction on the lower insulating layer, a first gate line on a first side surface of the back-gate line, a second gate line on a second side surface of the back gate line, first semiconductor patterns between the back-gate line and the first gate line, and second semiconductor patterns between the back-gate line and the second gate line, wherein the first semiconductor patterns and the second semiconductor patterns are offset in the first direction.

A semiconductor memory device according to some embodiments of the disclosed concepts may include a peripheral circuit structure including peripheral circuits on a substrate; and a cell structure electrically connected to the peripheral circuit structure, wherein the cell structure includes a lower insulating layer, bit lines in the lower insulating layer, a back-gate line extending in a first direction on the lower insulating layer; a first gate line and a second gate line spaced apart from one another with the back-gate line therebetween; first semiconductor patterns between the back-gate line and the first gate line; second semiconductor patterns between the Back-gate line and the second gate line; and data storage patterns on the first semiconductor patterns and the second semiconductor patterns, wherein the first semiconductor patterns and the second semiconductor patterns are arranged in a shape of zigzag in a plan view.

A method of manufacturing a semiconductor memory device according to some embodiments of the disclosed concepts may include forming a semiconductor layer on a substrate, forming back-gate lines extending in a first direction in the semiconductor layer, forming a spacer layer on the semiconductor layer and the back-gate lines, forming spacers from the spacer layer, and forming first semiconductor patterns and second semiconductor patterns from the semiconductor layer using the spacers, wherein the first semiconductor patterns and the second semiconductor patterns are arranged in a shape of zigzag in a plan view.

In the method of manufacturing a semiconductor device according to embodiments, forming the spacers from the spacer layer may include forming mask patterns on the spacer layer.

In the method of manufacturing a semiconductor device according to embodiments, the mask patterns may be arranged in a shape of zigzag, in a plan view.

In the method of manufacturing a semiconductor device according to embodiments, each of the mask patterns may extend in a diagonal direction with respect to the first direction and a second direction intersecting the first direction.

In the method of manufacturing a semiconductor device according to embodiments, the method may further include forming data storage devices on each of the first semiconductor patterns and the second semiconductor patterns, wherein the data storage devices partially overlap with the corresponding first semiconductor patterns and second semiconductor patterns.

### BRIEF DESCRIPTION OF THE DRAWINGS

FIG. 1 is a block diagram illustrating a semiconductor memory device according to embodiments of the disclosed concepts.

FIGS. 2 and 3 are perspective views illustrating a semiconductor memory device according to embodiments of the disclosed concepts.

FIG. 4 is a plan view illustrating a semiconductor memory device according to embodiments of the disclosed concepts.

FIGS. 5A-5C are diagrams illustrating a semiconductor memory device according to embodiments of the disclosed concepts, and are cross-sectional views taken along line A-A′, line B-B′, and line C-C′ of FIG. 4.

FIG. 6 is an enlarged view of the X region of FIG. 4.

FIGS. 7A and 7B are enlarged views of the Y region of FIG. 4.

FIGS. 8A to 8C are plan views illustrating a semiconductor memory device according to embodiments of the disclosed concepts.

FIGS. 9A and 9B are diagrams illustrating a semiconductor memory device according to embodiments of the disclosed concepts, and are cross-sectional views taken along line A-A′ of FIG. 4.

FIGS. 10 to 20B are diagrams for describing a method of manufacturing a semiconductor memory device according to embodiments of the disclosed concepts.

### DETAILED DESCRIPTION

Example embodiments of the disclosed concepts will now be described more fully with reference to the accompanying drawings, in which example embodiments are shown.

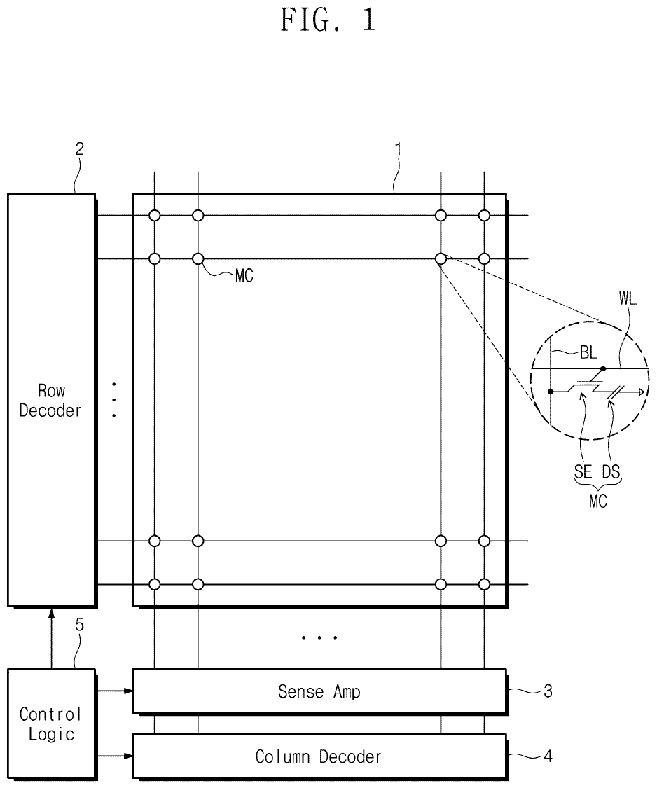

FIG. 1 is a block diagram illustrating a semiconductor memory device according to embodiments of the disclosed concepts.

Referring to FIG. 1, a semiconductor memory device may include a memory cell array 1, a row decoder 2, a sense amplifier 3, a column decoder 4, and a control logic 5.

The memory cell array 1 may include a plurality of memory cells MC that are two-dimensionally or three-dimensionally arranged. Each of the plurality of memory cells MC may be connected between word lines WL and bit lines BL that intersect with one another.

Each of the plurality of memory cells MC may include a selection device SE and a data storage device DS. The selection device SE and the data storage device DS may be electrically connected to one another. The selection device SE may be connected to corresponding word lines WL and bit lines BL. In other words, the selection device SE may be located at a point where the word lines WL and the bit lines BL intersect with one another.

The selection device SE may include a field-effect transistor. The data storage device DS may include a capacitor, a magnetic tunnel junction pattern, or a variable resistor. For example, a gate terminal of a transistor that is the selection device SE may be connected to one of the word lines WL, and each of source/drain terminals of the transistor may be connected to the data storage device DS and one of the bit lines BL.

The row decoder 2 may decode an externally input address, and may select one of the word lines WL of the memory cell array 1. The address decoded at the row decoder 2 may be provided to a row driver, which may provide a voltage to the word lines WL in response to control of the control circuits.

The sense amplifier 3 may sense, amplify and output the voltage difference of the bit lines BL according to the address decoded from the column decoder 4.

The column decoder 4 may provide a data transfer path between the sense amplifier 3 and an external device (e.g., a memory controller). The column decoder 4 may decode an externally input address to select the bit lines BL.

The control logic 5 may generate a control signal that controls an operation of writing or reading data into the memory cell array 1.

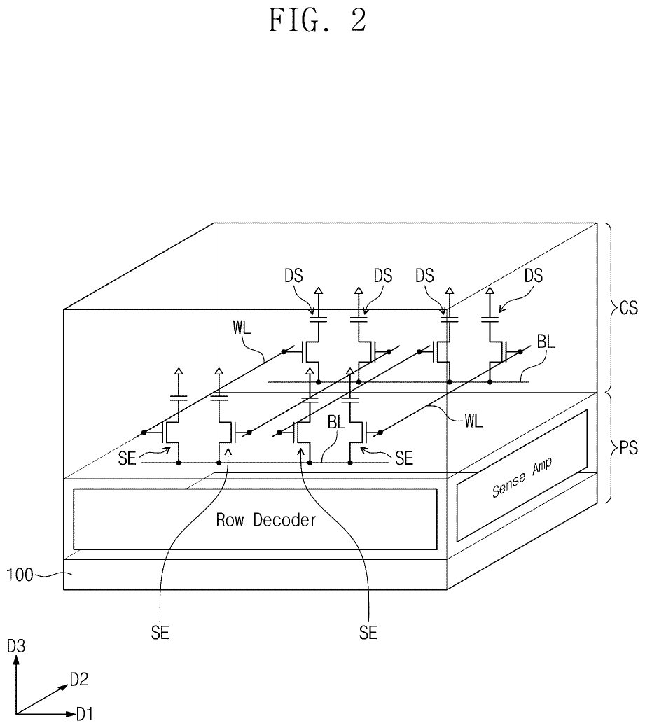

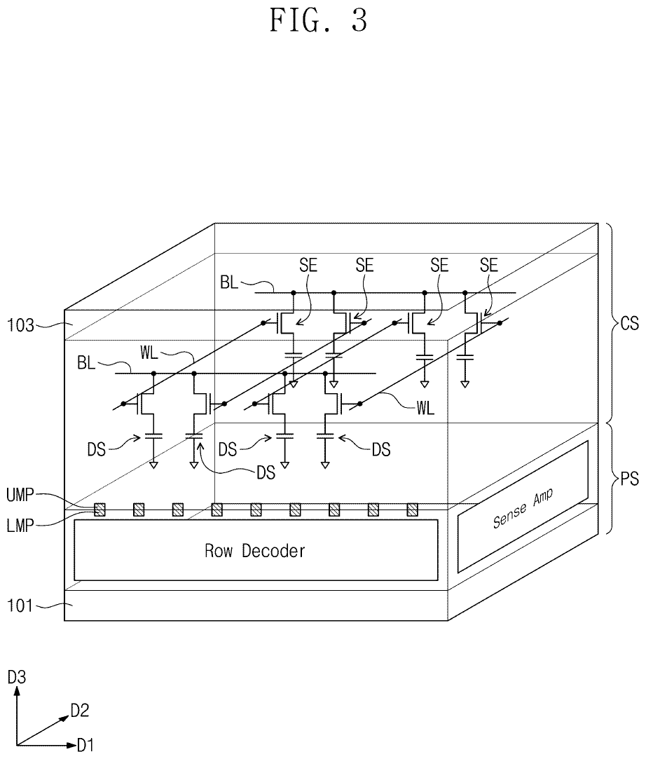

FIGS. 2 and 3 are perspective views illustrating a semiconductor memory device according to embodiments of the disclosed concepts.

Referring to FIG. 2, the semiconductor memory device may include a peripheral circuit structure PS and a cell structure CS connected to the peripheral circuit structure PS.

The peripheral circuit structure PS may include core and peripheral circuits formed on a substrate 100. The core and peripheral circuits may include the row decoder 2, the column decoder 4, the sense amplifier 3, and the control logic 5 described with reference to FIG. 1.

The cell structure CS may include a memory cell array 1 including two-dimensionally or three-dimensionally arranged memory cells MC described with reference to FIG. 1. As described above, each of the memory cells MC may include the selection device SE and the data storage device DS. For example, the selection device SE of each of the memory cells MC may include a vertical channel transistor (VCT). The vertical channel transistor may include a channel whose lengthwise direction is a direction perpendicular to the top surface of the substrate 100. In addition, the data storage device DS of each of the memory cells MC may include a capacitor.

The peripheral circuit structure PS may be provided on the substrate 100, and the cell structure CS may be provided on a peripheral circuit structure PS. For example, after the peripheral circuit structure PS is first formed on the substrate 100, the cell structure CS may be formed on the peripheral circuit structure PS. Alternatively, after the cell structure CS is first formed, the peripheral circuit structure PS may be formed.

Referring to FIG. 3, the peripheral circuit structure PS may be provided on a first substrate 101, and the cell structure CS may be provided on a second substrate 103. For example, each of the peripheral circuit structure PS and the cell structure CS may be formed on each of the first substrate 101 and the second substrate 103 and then bonded to one another. In this case, first metal pads LMP may be provided at an uppermost of the peripheral circuit structure PS. The first metal pads LMP may be electrically connected to the core and peripheral circuits. Second metal pads UMP may be provided at a lowermost of the cell structure CS. The second metal pads UMP may be electrically connected to the memory cell array. The second metal pads UMP may be bonded in direct contact with the first metal pads LMP of the peripheral circuit structure PS.

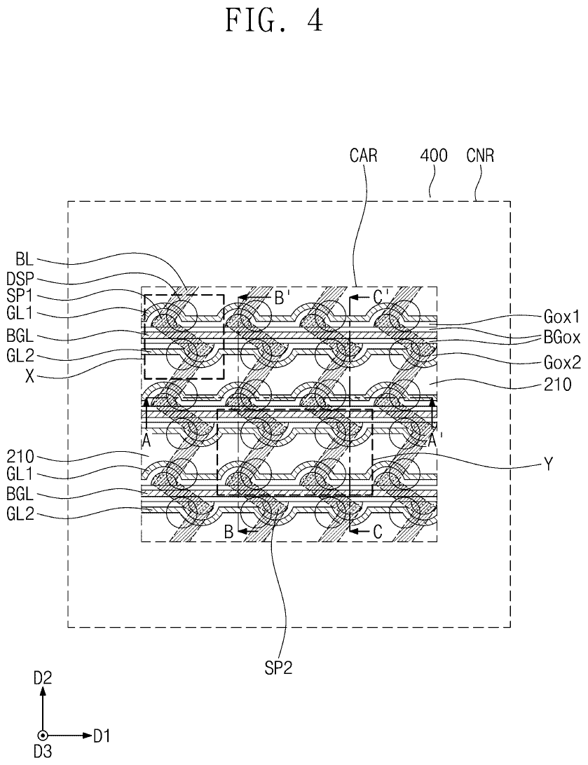

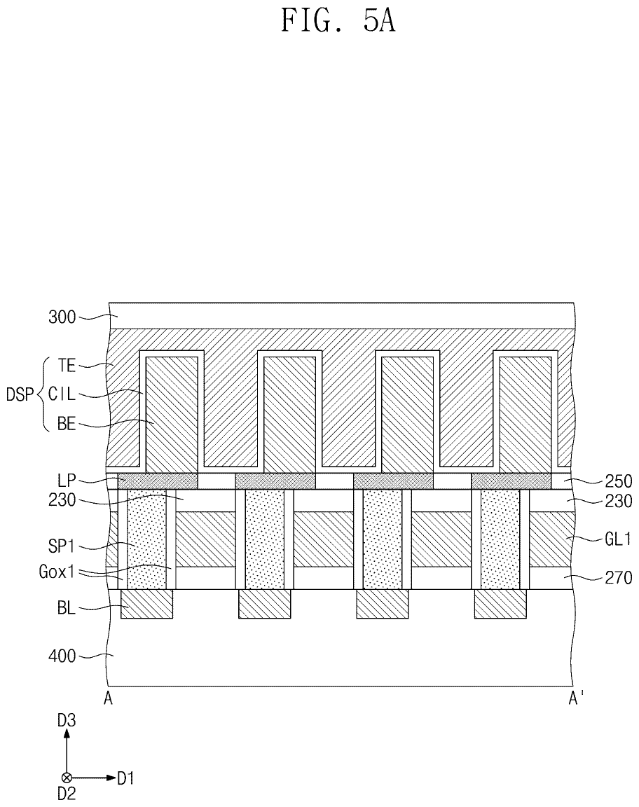

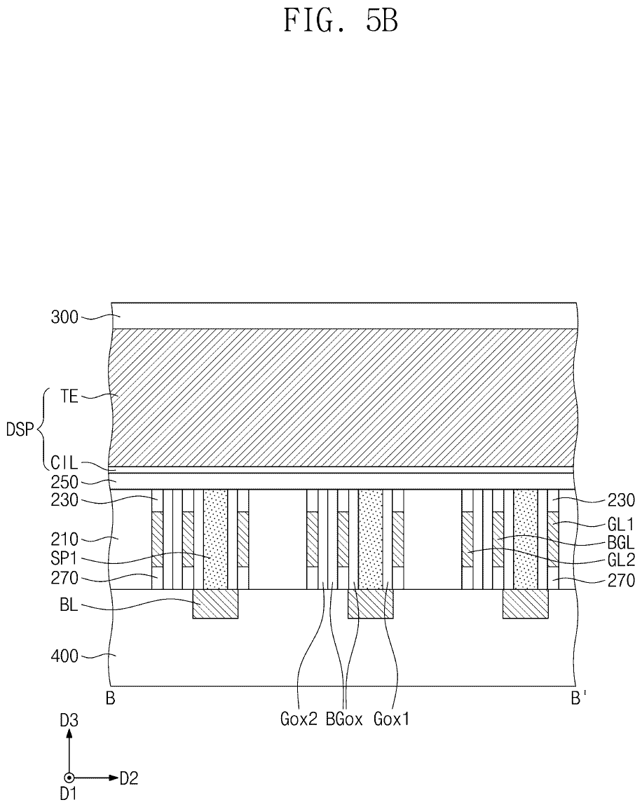

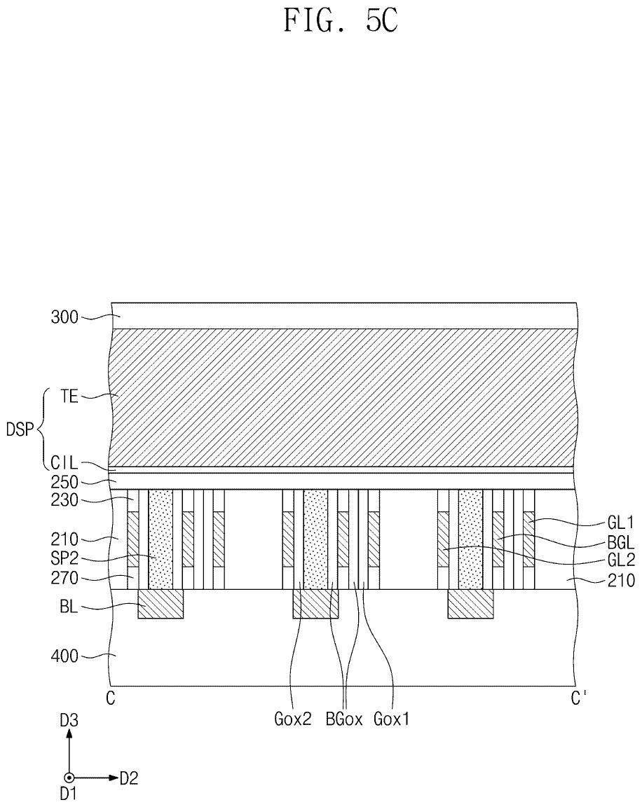

FIG. 4 is a plan view illustrating a semiconductor memory device according to embodiments of the disclosed concepts. FIGS. 5A to 5C are diagrams illustrating a semiconductor memory device according to embodiments of the disclosed concepts, and are cross-sectional views taken along line A-A′, line B-B′, and line C-C′ of FIG. 4.

Referring to FIG. 4 and FIGS. 5A to 5C, a semiconductor memory device of the disclosed concepts may be provided. For example, the semiconductor memory device may correspond to the cell structure CS described with reference to FIGS. 2 and 3.

The semiconductor memory device may include a lower insulating layer 400 including a cell array region CAR and a connection region CNR. The lower insulating layer 400 may extend in a first direction D1 and a second direction D2 from the cell array region CAR toward the connection region CNR. In a plan view, the connection region CNR may surround the cell array region CAR. However, the present invention is not limited thereto, and the connection region CNR may be disposed on a side of the cell array region CAR.

In the present specification, the first direction D1 and the second direction D2 may be parallel to a top surface of the lower insulating layer 400. The first direction D1 and the second direction D2 may intersect with one another. A third direction D3 may intersect the first direction D1 and the second direction D2, and may be a direction perpendicular to the top surface of the lower insulating layer 400. The first direction D1 and the second direction D2 may also be referred to as a horizontal direction. The third direction D3 may also be referred to as a vertical direction. For example, the first direction D1, the second direction D2, and the third direction D3 may be orthogonal to one another.

According to embodiments, the lower insulating layer 400 may include a plurality of insulating layers stacked in the third direction D3. The lower insulating layer 400 may have a multi-layer structure. For example, the lower insulating layer 400 may include an insulating material such as silicon oxide, silicon nitride, silicon oxynitride, and/or a low dielectric constant material.

Bit lines BL may be provided in the lower insulating layer 400. Each of the bit lines BL may extend along the second direction D2 and may be spaced apart from one another in the first direction D1. More specifically, each of the bit lines BL may extend in a diagonal direction with respect to the first direction D1 and the second direction D2. In addition, each of the bit lines BL may extend in two or more different directions. For example, each of the bit lines BL may extend in a zigzag direction. A top surface of each of the bit lines BL may be coplanar with the top surface of the lower insulating layer 400. For example, the bit lines BL may include at least one of doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide, or a conductive metal oxide (e.g., PtO, RuO₂, IrO₂, SRO (SrRuO₃), BSRO ((Ba,Sr)RuO₃) and CRO (CaRuO₃) or LSCo), but are not limited thereto.

According to embodiments, each of the bit lines BL may include a single layer or multiple layers of the above-described materials. The bit lines BL may include a two-dimensional semiconductor material such as a graphene and a carbon nanotube.

Back-gate lines BGL may be provided on the lower insulating layer 400. Each of the back-gate lines BGL may cross the bit lines BL and extend in the first direction D1. The back-gate lines BGL may be spaced apart from one another in the second direction D2. Each of the back-gate lines BGL may have a uniform width in the second direction D2. The back-gate lines BGL may adjust threshold voltages of transistors of the semiconductor memory device. As a result, electrical characteristics of the semiconductor memory device may be improved.

First gate lines GL1 and second gate lines GL2 crossing the bit lines BL may be provided on the lower insulating layer 400. For example, a pair of first and second gate lines GL1 and GL2 may be disposed on both side surfaces of each of the back-gate lines BGL. Each of the first gate lines GL1 and the second gate lines GL2 may extend in the first direction D1 and may be spaced apart from one another in the second direction D2. In a plan view, the first gate lines GL1 and the second gate lines GL2 may have a shape of wave embossing by first semiconductor patterns SP1 and second semiconductor patterns SP2 to be described later.

The back-gate lines BGL, the first gate lines GL1, and the second gate lines GL2 may include doped polysilicon, metal, conductive metal nitride, conductive metal silicide, conductive metal oxide, or a combination thereof. For example, the back-gate lines BGL, the first gate lines GL1, and the second gate lines GL2 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but are not limited thereto.

A lower buried layer 270 may be provided below the back-gate lines BGL, the first gate lines GL1, and the second gate lines GL2. The lower buried layer 270 may be positioned between the back-gate lines BGL and the lower insulating layer 400, between the first gate lines GL1 and the lower insulating layer 400, and between the second gate lines GL2 and the lower insulating layer 400. Therefore, the back-gate lines BGL, the first gate lines GL1, and the second gate lines GL2 may be spaced apart from the lower insulating layer 400 and the bit lines BL in the third direction D3. For example, the lower buried layer 270 may include an insulating material such as silicon oxide, silicon nitride, silicon oxynitride, and/or a low dielectric constant material.

An upper buried layer 230 may be provided on the back-gate lines BGL, the first gate lines GL1, and the second gate lines GL2. The upper buried layer 230 may be positioned between the back-gate lines BGL and an interlayer insulating layer 250, between the first gate lines GL1 and the interlayer insulating layer 250, and between the second gate lines GL2 and the interlayer insulating layer 250. Therefore, the back-gate lines BGL, the first gate lines GL1, and the second gate lines GL2 may be spaced apart from data storage patterns DSP to be described later in the third direction D3. For example, the upper buried layer 230 may include the same insulating material as the lower buried layer 270.

First semiconductor patterns SP1 may be two-dimensionally arranged on the lower insulating layer 400. The first semiconductor patterns SP1 may be positioned between the back-gate lines BGL and the first gate lines GL1. The first semiconductor patterns SP1 between the back-gate lines BGL and the first gate lines GL1 adjacent to one another may be spaced apart from one another in the first direction D1. Each of the first semiconductor patterns SP1 may extend from the top surface of the lower insulating layer 400 in the third direction D3. A vertical length in the third direction D3 of each of the first semiconductor patterns SP1 may be greater than a vertical length in the third direction D3 of each of the back-gate lines BGL, the first gate lines GL1, and the second gate lines GL2.

Second semiconductor patterns SP2 may be two-dimensionally arranged and spaced apart from the first semiconductor patterns SP1 on the lower insulating layer 400. The second semiconductor patterns SP2 may be positioned between the back-gate lines BGL and the second gate lines GL2. The second semiconductor patterns SP2 between the back-gate lines BGL and the second gate lines GL2 adjacent to one another may be spaced apart from one another in the first direction D1. Each of the second semiconductor patterns SP2 may extend from the top surface of the lower insulating layer 400 in the third direction D3. The second semiconductor patterns SP2 may have the same vertical length in the third direction D3 as the first semiconductor patterns SP1.

The first semiconductor patterns SP1 and the second semiconductor patterns SP2 may be positioned on corresponding bit lines BL on the cell array region CAR of the lower insulating layer 400. The first semiconductor patterns SP1 and the second semiconductor patterns SP2 may be electrically connected and in contact with the corresponding bit lines BL. In other words, the first semiconductor patterns SP1 and the second semiconductor patterns SP2 may be spaced apart from one another in the first direction D1 and the second direction D2 on the bit lines BL. In a plan view, the first semiconductor patterns SP1 and the second semiconductor patterns SP2 may be arranged in a shape of zigzag. For example, the first semiconductor patterns SP1 and the second semiconductor patterns SP2 adjacent to one another may be offset in the first direction D1.

The first semiconductor patterns SP1 and the second semiconductor patterns SP2 may include silicon. For example, the first semiconductor patterns SP1 and the second semiconductor patterns SP2 may include single crystal silicon doped with impurities or undoped single crystal silicon. The first semiconductor patterns SP1 and the second semiconductor patterns SP2 extending in the third direction D3 may function as a channel of the transistors of the semiconductor memory device. That is, the semiconductor memory device may include a vertical channel transistor having a channel extending in the third direction D3. Thus, the integration level of the semiconductor memory device may be improved.

Back-gate insulating layers BGox may be provided on both side surfaces of each of the back-gate lines BGL. Each of the back-gate insulating layers BGox may extend in the first direction D1 along the back-gate lines BGL. The back-gate insulating layers BGox may be positioned between the back-gate lines BGL and the first semiconductor patterns SP1 and between the back-gate line BGL and second semiconductor patterns SP2. The back-gate insulating layers BGox may be in contact with the back-gate lines BGL, the first semiconductor patterns SP1, and the second semiconductor patterns SP2.

First gate insulating layers Gox1 may be provided between the first gate lines GL1 and the first semiconductor patterns SP1. Second gate insulating layers Gox2 may be provided between the second gate lines GL2 and the second semiconductor patterns SP2. The first gate insulating layers Gox1 may partially be in contact with the first semiconductor patterns SP1. The first gate insulating layers Gox1 may be in contact with the back-gate insulating layers BGox in a region not in contact with the first semiconductor patterns SP1. The second gate insulating layers Gox2 may partially be in contact with the second semiconductor patterns SP2. The second gate insulating layers Gox2 may be in contact with the back-gate insulating layers BGox in a region not in contact with the second semiconductor patterns SP2. That is, each of the first gate insulating layers Gox1 and the second gate insulating layers Gox2 may be partially in contact with the back-gate insulating layers BGox.

Each of the first gate insulating layers Gox1 and the second gate insulating layers Gox2 may extend in the first direction D1 along the corresponding first gate lines GL1 and second gate lines GL2. For example, each of the first gate insulating layers Gox1 and the second gate insulating layers Gox2 may have a same planar profile as the corresponding first gate lines GL1 and second gate lines GL2. In a plan view, the first gate insulating layers Gox1 and the second gate insulating layers Gox2 may have a shape of wave embossing.

The back-gate insulating layers BGox, the first gate insulating layers Gox1, and the second gate insulating layers Gox2 may include silicon oxide, silicon oxynitride, silicon nitride, a high dielectric constant material, or a combination thereof. Herein, the high dielectric constant material may be a material having a dielectric constant higher than that of silicon oxide. For example, the high dielectric constant material may include HfO₂, HfSiO, HfSiON, HfTaO, HfTiO, HfZrO, ZrO₂, Al₂O₃, or a combination thereof.

Each of capping insulating patterns 210 may be provided between a pair of back-gate lines BGL. Each of the capping isolation patterns 210 may be located between the first gate line GL1 adjacent to one of the pair of back-gate lines BGL and the second gate line GL2 adjacent to the other of the pair of Back-gate lines BGL. For example, the capping insulating patterns 210 may extend in the first direction D1 between the first gate lines GL1 and the second gate lines GL2 adjacent in the second direction D2. The capping insulating patterns 210 may be in contact with the top surface of the lower insulating layer 400. For example, the capping insulating patterns 210 may include the insulating material such silicon oxide, silicon nitride, silicon oxynitride, and/or the low dielectric constant material.

An interlayer insulating layer 250 may be provided on the first semiconductor patterns SP1, the second semiconductor patterns SP2, and the capping insulating patterns 210. The interlayer insulating layer 250 may be in contact with the first semiconductor patterns SP1, the second semiconductor patterns SP2, the capping insulating patterns 210, and the upper buried layer 230 and may cover them with a uniform thickness.

Landing pads LP may be provided in the interlayer insulating layer 250. Each of the landing pads LP may be located on the corresponding first semiconductor patterns SP1 and second semiconductor patterns SP2. Each of the landing pads LP may be in contact with the corresponding first semiconductor patterns SP1 and second semiconductor patterns SP2. The landing pads LP may be electrically connected to the bit lines BL through the first semiconductor patterns SP1, and the second semiconductor patterns SP2. For example, the landing pads LP may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

Data storage patterns DSP may be provided on the interlayer insulating layer 250. The data storage patterns DSP may be two-dimensionally arranged. Each of the data storage patterns DSP may partially overlap the corresponding first semiconductor patterns SP1 and second semiconductor patterns SP2. That is, each of the data storage patterns DSP may vertically overlap portions of the corresponding first semiconductor patterns SP1 and second semiconductor patterns SP2. The data storage patterns DSP may be electrically connected to the corresponding first semiconductor patterns SP1 and second semiconductor patterns SP2 through the landing pads LP. In a plan view, the data storage patterns DSP may be arranged in a shape of matrix. However, the present disclosed concepts is not limited thereto, and the data storage patterns DSP may be arranged in a shape of honeycomb.

The data storage patterns DSP may include bottom electrodes BE, a top electrode TE, and a capacitor dielectric layer CIL between the bottom electrodes BE and the top electrode TE. Each of the bottom electrodes BE may extend in the third direction D3 on the corresponding landing pads LP. Each of the bottom electrodes BE may be in contact with the corresponding landing pads LP. Each of the bottom electrodes BE may be offset in the first direction D1 with respect to the corresponding first semiconductor patterns SP1 and second semiconductor patterns SP2. Accordingly, each of the landing pads LP may have a larger planar width (or horizontal width) than the bottom electrodes BE, the first semiconductor patterns SP1, and the second semiconductor patterns SP2.

The capacitor dielectric layer CIL of the data storage patterns DSP may cover the bottom electrodes BE with a uniform thickness. The capacitor dielectric layer CIL may extend on the interlayer insulating layer 250 from the lower electrodes BE. The capacitor dielectric layer CIL may partially in contact with the landing pads LP.

The top electrode TE of the data storage patterns DSP may be one top electrode TE covering a plurality of bottom electrodes BE, but is not limited thereto.

According to embodiments, the data storage patterns DSP may include a magnetic tunnel junction pattern. In this case, the semiconductor memory device according to the disclosed concepts may be a magnetic random access memory (MRAM). According to embodiments, the data storage patterns DSP may include a phase change material or a variable resistance material. In this case, the semiconductor memory device according to the disclosed concepts may be a phase-change random access memory (PRAM) or a resistive random access memory (ReRAM). However, the disclosed concepts is not limited thereto, and the data storage patterns DSP may include various structures and/or materials capable of storing data.

An upper insulating layer 300 may be provided on the data storage patterns DSP. The upper insulating layer 300 may cover the top electrode TE of the data storage patterns DSP. The upper insulating layer 300 may include the same insulating material as the lower insulating layer 400, but is not limited thereto.

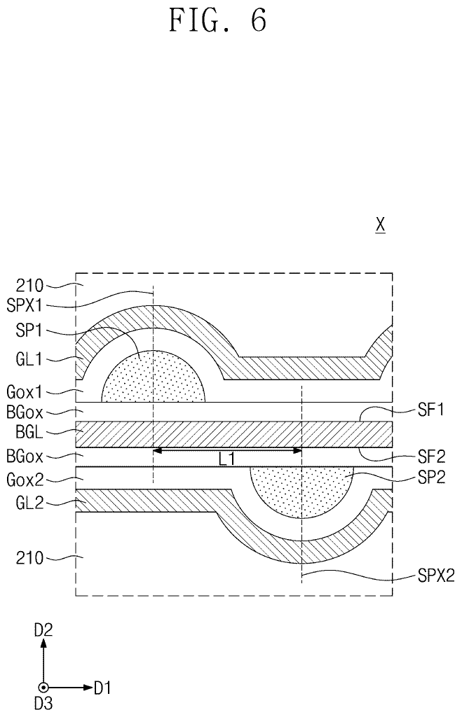

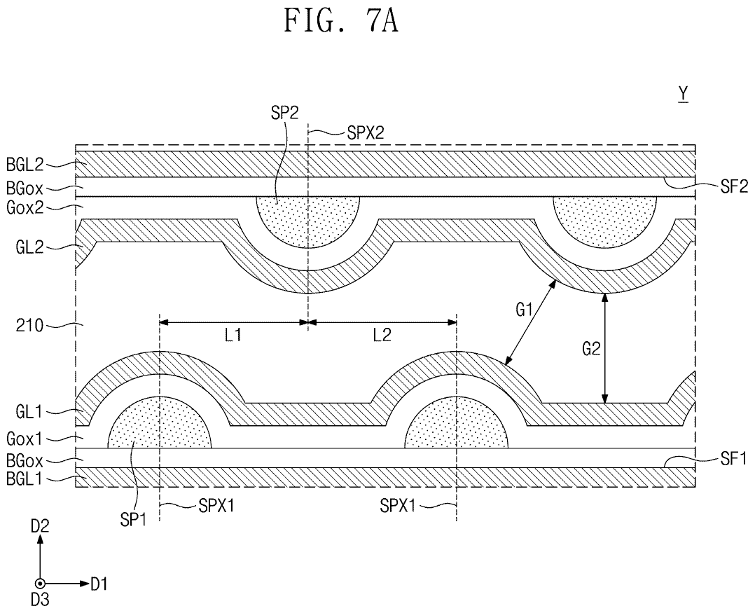

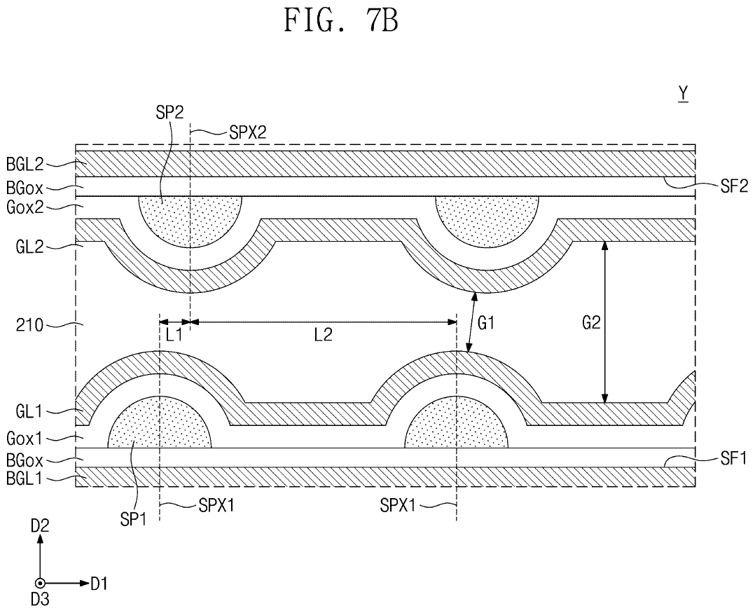

FIG. 6 is an enlarged view of the X region of FIG. 4. FIGS. 7A and 7B are enlarged views of the Y region of FIG. 4.

Referring to FIG. 6, the back-gate line BGL may have a first side surface SF1 and a second side surface SF2 extending in the first direction D1 and opposite to one another in the second direction D2. The back-gate insulating layer BGox may be provided on the first side surface SF1 and the second side surface SF2 of the back-gate line BGL, and may extend in the first direction D1 along the back-gate line BGL. The back-gate insulating layer BGox may cover and be in contact with the first side surface SF1 and the second side surface SF2 of the back-gate line BGL.

The first semiconductor pattern SP1 may be provided on the first side surface SF1 of the back-gate line BGL, and the second semiconductor pattern SP2 may be provided on the second side surface SF2 of the back-gate lines BGL. The first semiconductor pattern SP1 and the second semiconductor pattern SP2 adjacent to one another may be spaced apart from one another in the second direction D2 with respect to the back-gate line BGL. The first semiconductor pattern SP1 may be in contact with the back-gate insulating layer BGox covering the first side surface SF1 of the back-gate line BGL. The second semiconductor pattern SP2 may be in contact with the back-gate insulating layer BGox covering the second side surface SF2 of the back-gate line BGL. In a plan view, each of the first semiconductor pattern SP1 and the second semiconductor pattern SP2 may have a shape of semicircular. However, the disclosed concepts is not limited thereto, and each of the first semiconductor pattern SP1 and the second semiconductor pattern SP2 may have a planar shape of a triangle, a square, and/or a polygon.

The first semiconductor pattern SP1 may have a first axis SPX1 penetrating therein in the second direction D2. The second semiconductor pattern SP2 may have a second axis SPX2 penetrating therein in the second direction D2. For example, the first axis SPX1 may pass through a center of the first semiconductor pattern SP1 along the first direction D1, and the second axis SPX2 may pass through a center of the second semiconductor pattern SP2 along the first direction D1.

The first axis SPX1 of the first semiconductor pattern SP1 and the second axis SPX2 of the second semiconductor pattern SP2 may be spaced apart from one another in the first direction D1. For example, the first axis SPX1 and the second axis SPX2 may be spaced apart from one another by a first length L1 in the first direction D1. The first semiconductor pattern SP1 and the second semiconductor pattern SP2 adjacent to one another may be offset in the first direction D1 and spaced apart from one another in the first direction D1. Accordingly, the first semiconductor pattern SP1 and the second semiconductor pattern SP2 adjacent to one another may be spaced apart from one another in a diagonal direction with respect to the first direction D1 and the second direction D2.

The first gate insulating layer Gox1 and the first gate line GL1 being in contact with one another may be sequentially positioned on the first side surface SF1 of the back-gate line BGL. The first gate insulating layer Gox1 may be closer to the back-gate line BGL than the first gate line GL1. The first gate insulating layer Gox1 may extend on the back-gate insulating layer BGox while covering side surfaces of the first semiconductor pattern SP1. The first gate insulating layer Gox1 may be partially in contact with the first semiconductor pattern SP1 and the back-gate insulating layer BGox. Accordingly, the first gate insulating layer Gox1 may include a convex portion covering the first semiconductor pattern SP1 and a flat portion covering the back-gate insulating layer BGox. The first gate line GL1 may have the same planar profile as the first gate insulating layer Gox1. For example, the first gate line GL1 may have a convex portion protruding from the first side surface SF1 of the back-gate line BGL due to the first semiconductor pattern SP1.

The second gate insulating layer Gox2 and the second gate line GL2 being in contact with one another may be sequentially positioned on the second side surface SF2 of the back-gate line BGL. The second gate insulating layer Gox2 may be closer to the back-gate line BGL than the second gate line GL2. The second gate insulating layer Gox2 may extend on the back-gate insulating layer BGox while covering side surfaces of the second semiconductor pattern SP2. Like the first gate insulating layer Gox1, the second gate insulating layer Gox2 may include a convex portion covering the second semiconductor pattern SP2 and a flat portion covering the back-gate insulating layer BGox. The second gate line GL2 may have a same planar profile as the second gate insulating layer Gox2. For example, the second gate line GL2 may have a convex portion protruding from the second side surface SF2 of the back-gate line BGL due to the second semiconductor pattern SP2.

Capping insulating patterns 210 may be provided on a side surface of each of the first gate line GL1 and the second gate line GL2. The capping insulating patterns 210 may be spaced apart from the first semiconductor pattern SP1, the second semiconductor pattern SP2, and the back-gate line BGL by the first gate line GL1 and the second gate line GL2, therebetween.

Referring to FIGS. 7A and 7B, a pair of back-gate lines BGL may be provided. The pair of back-gate lines BGL may include a first back-gate line BGL1 and a second back-gate line BGL2. Each of the first and second back-gate lines BGL1 and BGL2 may extend in the first direction D1 and be spaced apart from one another in the second direction D2.

Each of the first and second back-gate lines BGL1 and BGL2 may have the first side surface SF1 and the second side surface SF2 opposite to one another. The first side surface SF1 of the first back-gate line BGL1 and the second side surface SF2 of the second back-gate line BGL2 may face one another. The back-gate insulating layers BGox may be provided on the first side surface SF1 of the first back-gate line BGL1 and the second side surface SF2 of the second back-gate line BGL2. Each of the back-gate insulating layers BGox may extend in the first direction D1 along the first back-gate line BGL1 and the second back-gate line BGL2. Each of the back-gate insulating layers BGox may be in contact with the first side surface SF1 of the first back-gate line BGL1 and the second side surface SF2 of the second back-gate line BGL2.

The first semiconductor patterns SP1 may be provided on the first side surface SF1 of the first back-gate line BGL1. The first semiconductor patterns SP1 may be spaced apart from one another in the first direction D1 on the first side surface SF1 of the first back-gate line BGL1. The first semiconductor patterns SP1 may be in contact with the back-gate insulating layer BGox covering the first side surface SF1 of the first back-gate line BGL1. Each of the first semiconductor patterns SP1 may have the first axis SPX1 penetrating therein in the second direction D2.

The second semiconductor patterns SP2 may be provided on the second side surface SF2 of the second back-gate line BGL2. The second semiconductor patterns SP2 may be spaced apart from one another in the first direction D1 on the second side surface SF2 of the second back-gate line BGL2. The second semiconductor patterns SP2 may be in contact with the back-gate insulating layer BGox covering the second side surface SF2 of the second back-gate line BGL2. Each of the second semiconductor patterns SP2 may have the second axis SPX2 penetrating therein in the second direction D2.

According to embodiments of the disclosed concepts, the first semiconductor patterns SP1 and the second semiconductor patterns SP2 may be offset in the first direction D1 and spaced apart from one another in the first direction D1. The first axis SPX1 of each of the first semiconductor patterns SP1 and the second axis SPX2 of each of the second semiconductor patterns SP2 may not be aligned with one another. Each of the first semiconductor patterns SP1 may be located between two adjacent second semiconductor patterns SP2, and each of the second semiconductor patterns SP2 may be located between the two adjacent first semiconductor patterns SP1. For example, the first semiconductor patterns SP1 and the second semiconductor patterns SP2 may be alternately disposed along the first direction D1.

For example, a length in the first direction D1 between one of the second semiconductor patterns SP2 and one of the two adjacent first semiconductor patterns SP1 may be a first length L1. A length in the first direction D1 between one of the second semiconductor patterns SP2 and the other of the two adjacent first semiconductor patterns SP1 may be a second length L2.

According to embodiments, the first length L1 and the second length L2 between the first semiconductor patterns SP1 and the second semiconductor patterns SP2 may be substantially the same. In this case, each of the second semiconductor patterns SP2 may be aligned at a center of the two adjacent first semiconductor patterns SP1. Each of the first semiconductor patterns SP1 may be aligned at a center of the two adjacent second semiconductor patterns SP2. For example, distances between each of the first semiconductor patterns SP1 and the two adjacent second semiconductor patterns SP2 may be the same, and the distances between each second semiconductor pattern SP2 and the two adjacent first semiconductor patterns SP1 may be the same.

In this specification, the term ‘substantially the same’ may refer to a difference in specific values and/or properties being within about 10%. Accordingly, values and/or properties described in the disclosed concepts may be considered substantially the same when the difference is within about 10%.

According to embodiments, the first length L1 and the second length L2 between the first semiconductor patterns SP1 and the second semiconductor patterns SP2 may be different from one another. For example, the first length L1 may be less than the second length L2. In this case, each of the second semiconductor patterns SP2 may be further adjacent to any one of the two adjacent first semiconductor patterns SP1. Each of the first semiconductor patterns SP1 may be further adjacent to any one of the two adjacent second semiconductor patterns SP2. For example, the distances between each of the first semiconductor patterns SP1 and the two adjacent second semiconductor patterns SP2 may be different, and the distances between each of the second semiconductor pattern SP2 and the two adjacent first semiconductor patterns SP1 may be different.

The first gate insulating layer Gox1 and the first gate line GL1 being in contact with one another may be provided on the first side surface SF1 of the first back-gate line BGL1. The first gate insulating layer Gox1 may be closer to the first back-gate line BGL1 than the first gate line GL1. As described with reference to FIG. 6, the first gate insulating layer Gox1 may include the convex portion covering the first semiconductor patterns SP1 and the flat portion covering the back-gate insulating layer BGox. In addition, the first gate line GL1 may have substantially the same planar profile as the first gate insulating layer Gox1.

The second gate insulating layer Gox2 and the second gate line GL2 being in contact with one another may be provided on the second side surface SF2 of the second back-gate line BGL2. The second gate insulating layer Gox2 may be closer to the second back-gate line BGL2 than the second gate line GL2. As described with reference to FIG. 6, the second gate insulating layer Gox2 may include the convex portion covering the second semiconductor patterns SP2 and the flat portion covering the back-gate insulating layer BGox. In addition, the second gate line GL2 may have substantially the same planar profile as the second gate insulating layer Gox2.

The first gate line GL1 on the first side surface SF1 of the first back-gate line BGL1 and the second gate line GL2 on the second side surface SF2 of the second back-gate line BGL2 may be spaced apart from one another. For example, the first gate line GL1 and the second gate line GL2 may be horizontally spaced apart by a first interval G1 and a second interval G2. The first interval G1 may be a minimum interval between the first gate line GL1 and the second gate line GL2. The second interval G2 may be a maximum interval between the first gate line GL1 and the second gate line GL2. For example, each of the first interval G1 and the second interval G2 may range from about 10 nm to about 20 nm.

According to embodiments, the first interval G1 and the second interval G2 between the first gate line GL1 and the second gate line GL2 may be substantially the same. For example, a difference between the first interval G1 and the second interval G2 may be less than about 10%. In this case, the first gate line GL1 and the second gate line GL2 may be spaced apart from one another with a substantially uniform interval.

According to embodiments, the first interval G1 and the second interval G2 between the first gate line GL1 and the second gate line GL2 may be different from one another. For example, the first interval G1 may be less than the second interval G2. In this case, an interval between the first gate line GL1 and the second gate line GL2 may not be uniform, and may vary such that the interval becomes narrower or wider.

The capping insulating pattern 210 may be provided between the first gate line GL1 on the first side surface SF1 of the first back-gate line BGL1 and the second gate line GL2 on the second side surface SF2 of the second back-gate line BGL2. The capping insulating pattern 210 may extend in the first direction D1 between the first gate line GL1 and the second gate line GL2. The first back-gate line BGL1 and the first gate line GL1 may be electrically insulated from the second back-gate line BGL2 and the second gate line GL2 by the capping insulating pattern 210. The capping insulating pattern 210 may be in contact with and between the first gate line GL1 and the second gate line GL2. Accordingly, the first interval G1 and the second interval G2 between the first gate line GL1 and the second gate line GL2 may be a horizontal width of the capping insulating pattern 210. When the first interval G1 and the second interval G2 between the first gate line GL1 and the second gate line GL2 are substantially the same, the capping insulating pattern 210 may have a substantially uniform horizontal width. When the first interval G1 and the second interval G2 between the first gate line GL1 and the second gate line GL2 are different from one another, the capping insulating pattern 210 may have a substantially non-uniform horizontal width.

When the first semiconductor patterns SP1 and the second semiconductor patterns SP2 are not offset in the first direction D1 (or, aligned in the first direction D1), the first interval G1 between the first gate line GL1 and the second gate line GL2 may be the smallest. Accordingly, a parasitic capacitance may increase between the first gate line GL1 and the second gate line GL2. The difference between the first interval G1 and the second interval G2 may be the largest. For example, in the step of forming the capping insulating pattern 210 by a deposition process, a problem may occur in which a void is formed in the capping insulating pattern 210.

According to embodiments of the disclosed concepts, the first semiconductor patterns SP1 and the second semiconductor patterns SP2 may be offset in the first direction D1. In a plan view, the first semiconductor patterns SP1 and the second semiconductor patterns SP2 may be arranged in a shape of zigzag. As the first interval G1 between the first gate line GL1 and the second gate line GL2 increases, the difference between the first interval G1 and the second interval G2 may decrease. For example, the first interval G1 and the second interval G2 may be substantially the same. The void in the capping insulating pattern 210 and/or the parasitic capacitance between the first gate line GL1 and the second gate line GL2 may be prevented or reduced. Accordingly, electrical characteristics of the semiconductor memory device may be improved.

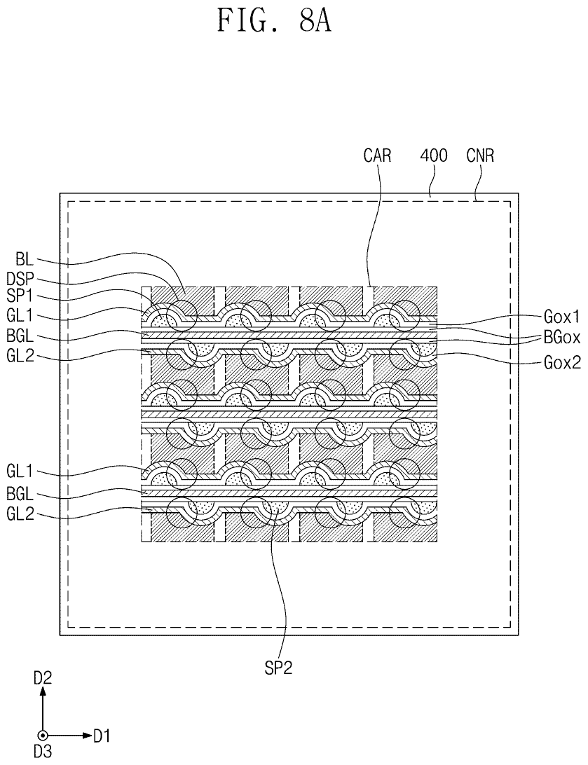

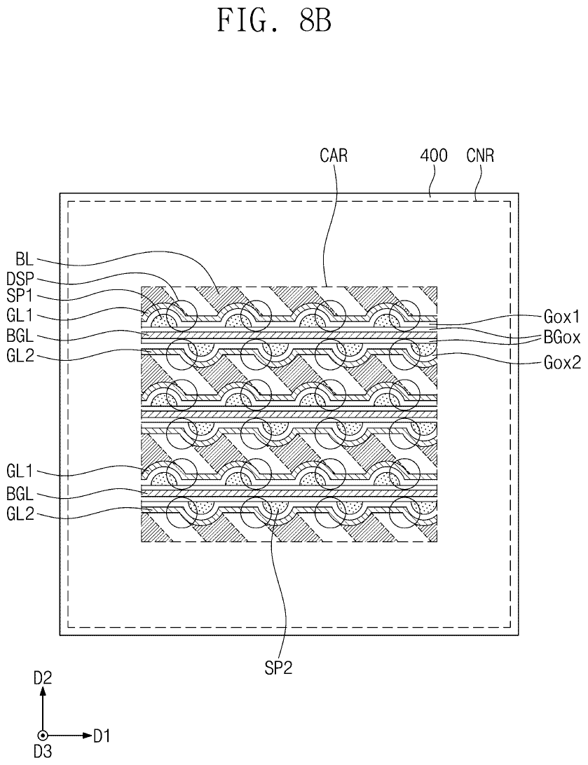

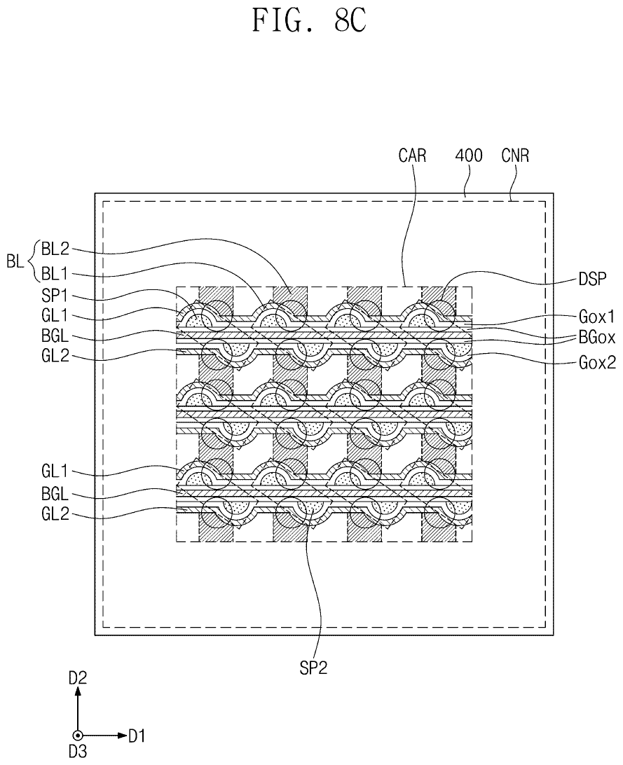

FIGS. 8A to 8C are plan views illustrating a semiconductor memory device according to embodiments of the disclosed concepts.

Referring to FIGS. 8A, 8B, and 8C, bit lines BL of a semiconductor memory device may be provided in various shapes. The bit lines BL may be positioned in the lower insulating layer 400, as described with reference to FIGS. 5A to 5C. Each of the bit lines BL may be in contact with the corresponding first semiconductor patterns SP1 and second semiconductor patterns SP2.

According to embodiments, referring to FIG. 8A, each of the bit lines BL may extend parallel to the second direction D2 and may be spaced apart from one another in the first direction D1. In a plan view, each of the bit lines BL may have a shape of line or bar. Each of the bit lines BL may vertically overlap the first semiconductor patterns SP1 and the second semiconductor patterns SP2 adjacent to one another. Since the first semiconductor patterns SP1 and the second semiconductor patterns SP2 are offset in the first direction D1, the horizontal width of each of the bit lines BL may be greater than the horizontal width of the bit lines BL described with reference to FIG. 4.

According to embodiments, referring to FIG. 8B, each of the bit lines BL may extend in a diagonal direction with respect to the first direction D1 and the second direction D2. Each of the bit lines BL may not be parallel to the first direction D1 and the second direction D2. For example, bit lines BL may intersect the back-gate lines BGL, but may not be orthogonal.

According to embodiments, referring to FIG. 8C, the bit lines BL may have a two-tiered structure stacked in the third direction D3. Each of the bit lines BL may include a first bit line BL1 and a second bit line BL2 below the first bit line BL1. The first bit line BL1 may vertically overlap and be connected to the first semiconductor patterns SP1 and the second semiconductor patterns SP2 adjacent to one another. The first bit line BL1 may extend in the diagonal direction with respect to the first direction D1 and the second direction D2. The second bit line BL2 may be connected to the first bit line BL1. The second bit line BL2 may extend in the second direction D2.

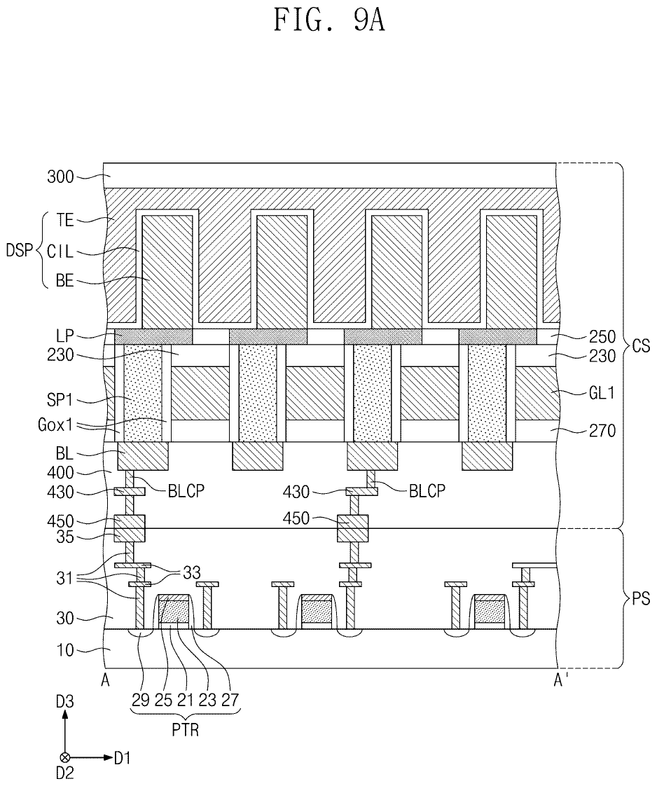

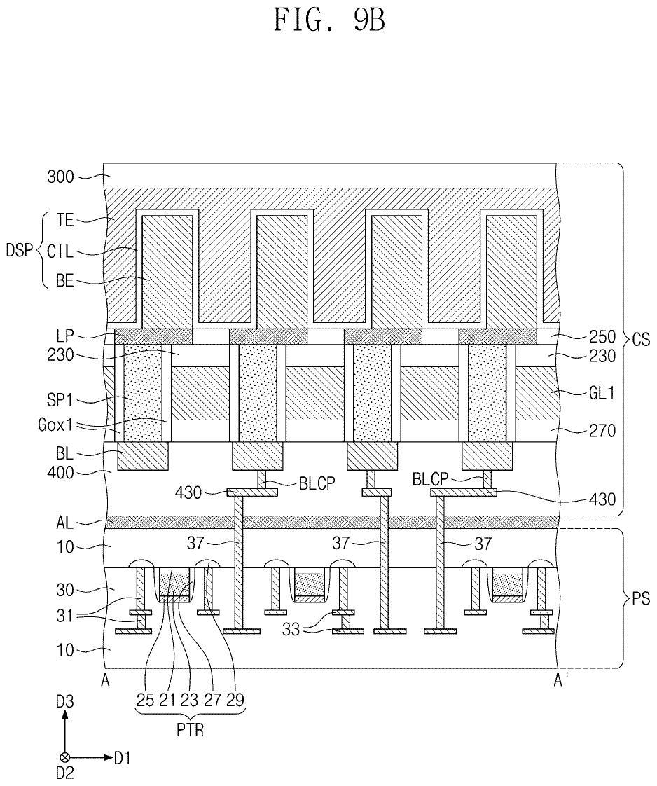

FIGS. 9A and 9B are diagrams illustrating a semiconductor memory device according to embodiments of the disclosed concepts, and are cross-sectional views taken along line A-A′ of FIG. 4.

Referring to FIGS. 9A and 9B, the semiconductor memory device may further include the peripheral circuit structure PS positioned below the cell structure CS and vertically overlapping the cell structure CS. The cell structure CS may be electrically connected to the peripheral circuit structure PS. However, the disclosed concepts is not limited thereto, and the peripheral circuit structure PS may be located on the cell structure CS, or the peripheral circuit structure PS may be located on a side of the cell structure CS.

Referring to FIG. 9A, bit line plugs BLCP may be provided in the lower insulating layer 400. The bit line plugs BLCP may be connected to the corresponding bit lines BL. The bit line plugs BLCP may be electrically connected to first bonding pads 450 through connection circuit wirings 430 and connection circuit plugs 410 in the lower insulating layer 400. The connection circuit wirings 430 and the connection circuit plugs 410 may include a conductive material such as a metal.

The first bonding pads 450 may be provided in the lower insulating layer 400 adjacent to a bottom surface of the lower insulating layer 400. The bottom surface of the lower insulating layer 400 may expose the bottom surfaces of the first bonding pads 450. For example, the bottom surface of the lower insulating layer 400 may be coplanar with the bottom surfaces of the first bonding pads 450.

The peripheral circuit structure PS may be positioned on the bottom surface of the lower insulating layer 400. The peripheral circuit structure PS may vertically overlap the lower insulating layer 400. The peripheral circuit structure PS may include a peripheral circuit substrate 10, a peripheral circuit transistors PTR on the peripheral circuit substrate 10, peripheral circuit plugs 31, peripheral circuit wirings 33 electrically connected to the peripheral circuit transistor PTR through the peripheral circuit plug 31, and the first insulating layer 30 surrounding them.

The peripheral circuit transistors PTR, the peripheral circuit plugs 31, and the peripheral circuit wirings 33 may constitute a peripheral circuit. Each of the peripheral circuit transistors PTR may include a peripheral gate insulating layer 21, a peripheral gate electrode 23, a peripheral capping pattern 25, a peripheral gate spacer 27, and peripheral source/drain regions 29.

The peripheral gate insulating layer 21 may be positioned between the peripheral gate electrode 23 and the peripheral circuit substrate 10. The peripheral capping pattern 25 may be located on the peripheral gate electrode 23. The peripheral gate spacer 27 may cover sidewalls of the peripheral gate insulating layer 21, the peripheral gate electrode 23, and the peripheral capping pattern 25. The peripheral source/drain regions 29 may be located in the peripheral circuit substrate 10 adjacent to both sides of the peripheral gate electrode 23.

The peripheral circuit wirings 33 may be electrically connected to the peripheral circuit transistors PTR through the peripheral circuit plugs 31. For example, each of the peripheral circuit transistors PTR may be an NMOS transistor, a PMOS transistor, or a gate-all-around transistor, but is not limited thereto. The peripheral circuit plugs 31 and the peripheral circuit wirings 33 may include a conductive material such as a metal.

The first insulating layer 30 may be provided on the peripheral circuit substrate 10. The first insulating layer 30 may cover the peripheral circuit transistors PTR, the peripheral contact plugs 31, and the peripheral circuit wirings 33 on the peripheral circuit substrate 10. The first insulating layer 30 may be formed of multiple layers. For example, the first insulating layer 30 may include silicon oxide, silicon nitride, silicon oxynitride, and/or the low dielectric material.

Second bonding pads 35 adjacent to a top surface of the first insulating layer 30 may be provided in the first insulating layer 30. The first insulating layer 30 may not cover top surfaces of the second bonding pads 35. For example, the top surface of the first insulating layer 30 may be coplanar with the top surfaces of the second bonding pads 35. The second bonding pads 35 may be electrically connected to the peripheral circuit transistors PTR through the peripheral circuit plugs 31 and the peripheral circuit wirings 33.

Each of the first bonding pads 450 may be in contact with corresponding second bonding pads 35. The bottom surfaces of the first bonding pads 450 and the top surfaces of the second bonding pads 35 may be in contact with one another, respectively. The first and second bonding pads 450 and 35 may be bonded by the intermetallic hybrid bonding. In this specification, hybrid bonding may denote a bonding in which two components of the same kind are merged at an interface therebetween. Thus, the first and second bonding pads 450 and 35 may be form as a single object without an interface therebetween.

Referring to FIG. 9B, an interface layer AL may be provided between the cell structure CS and the peripheral circuit structure PS. The interface layer may be in contact with the bottom surface of the lower insulating layer 400 and the peripheral circuit substrate 10. The peripheral circuit structure PS may include peripheral circuit vias 37 electrically connected to the peripheral circuit transistors PTR through the peripheral circuit plugs 31 and the peripheral circuit wirings 33. The peripheral circuit vias 37 may be connected to the connection circuit wirings 430 of the cell structure CS through the interface layer AL. Accordingly, the data storage patterns DSP of the cell structure CS and the peripheral circuit transistors PTR of the peripheral circuit structure PS may be electrically connected.

An insulating layer may be further provided between the sidewalls of the peripheral circuit vias 37 and the peripheral circuit substrate 10. Accordingly, the peripheral circuit vias 37 and the peripheral circuit substrate 10 may be electrically insulated from one another.

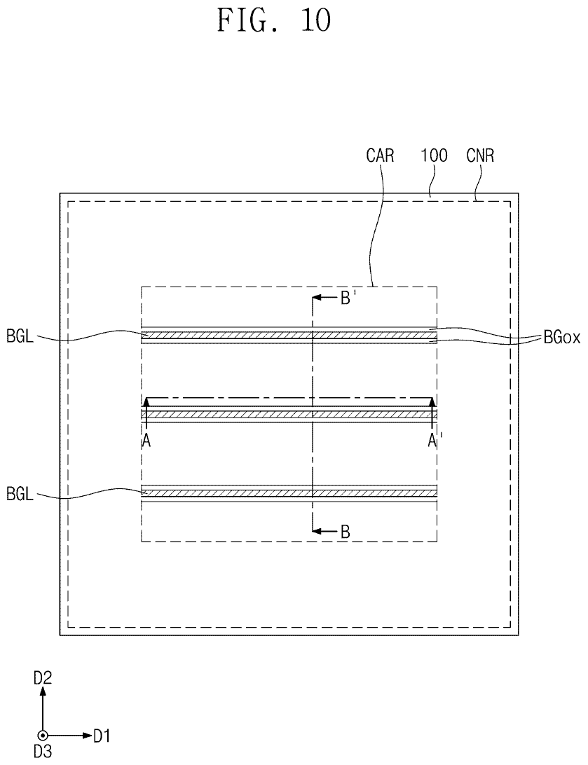

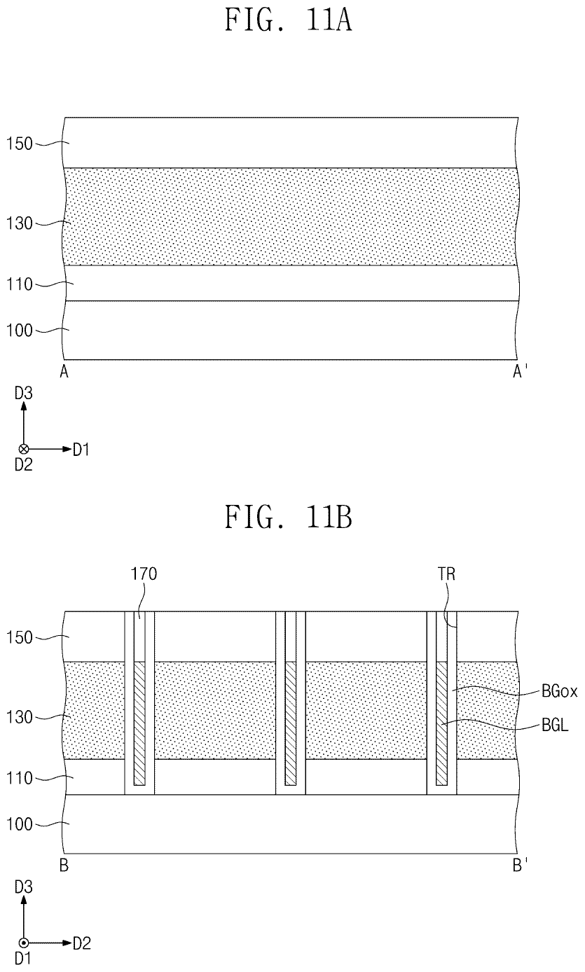

FIGS. 10 to 20B are diagrams for describing a method of manufacturing a semiconductor memory device according to embodiments of the disclosed concepts. FIGS. 10, 12, 14, 16, and 18 are plan views for describing a method of manufacturing a semiconductor memory device. FIGS. 11A, 13A, 15A, 17A, 19A, and 20A are diagrams taken along line A-A′ of FIGS. 10, 12, 14, 16, and 18, and FIG. 11B, FIGS. 13B, 15B, 17B, 19B, and 20B are diagrams taken along line B-B′ of FIGS. 10, 12, 14, 16, and 18.

Referring to FIGS. 10, 11A, and 11B, a substrate 100 may be provided. The substrate 100 may include a cell array region CAR and a connection region CNR adjacent to the cell array region CAR. In a plan view, the connection region CNR may surround the cell array region CAR. For example, the substrate 100 may be a silicon wafer. A first preliminary insulating layer 110, a semiconductor layer 130, and a second preliminary insulating layer 150 having a uniform thickness may be sequentially formed on the substrate 100.

The first preliminary insulating layer 110, the semiconductor layer 130, and the second preliminary insulating layer 150 may be formed by a deposition process. For example, the deposition process may include a physical vapor deposition (PVD) process, a chemical vapor deposition (CVD) process, and/or an atomic layer deposition (ALD) process. The first preliminary insulating layer 110 and the second preliminary insulating layer 150 may include different insulating materials. According to embodiments, the first preliminary insulating layer 110 may include silicon oxide, and the second preliminary insulating layer 150 may include silicon nitride. The semiconductor layer 130 may include single crystal silicon. More specifically, the semiconductor layer 130 may include single crystal silicon doped with impurities or undoped single crystal silicon.

Thereafter, trenches TR penetrating the first preliminary insulating layer 110, the semiconductor layer 130, and the second preliminary insulating layer 150 may be formed. Each of the trenches TR may extend in a first direction D1 and be spaced apart from one another in a second direction D2. A bottom surface of each of the trenches TR may expose a top surface of the substrate 100.

Back-gate insulating layers BGox, back-gate lines BGL, and back-gate capping layers 170 may be sequentially formed in the trenches TR. The back-gate insulating layers BGox may cover inner walls of the trenches TR with a uniform thickness. The back-gate lines BGL may fill a lower portion of the trenches TR. The back-gate capping layers 170 may fill a top end of the trenches TR on the back-gate lines BGL. Each of the back-gate lines BGL may extend along the trenches TR in the first direction D1 and may be spaced apart from one another in the second direction D2.

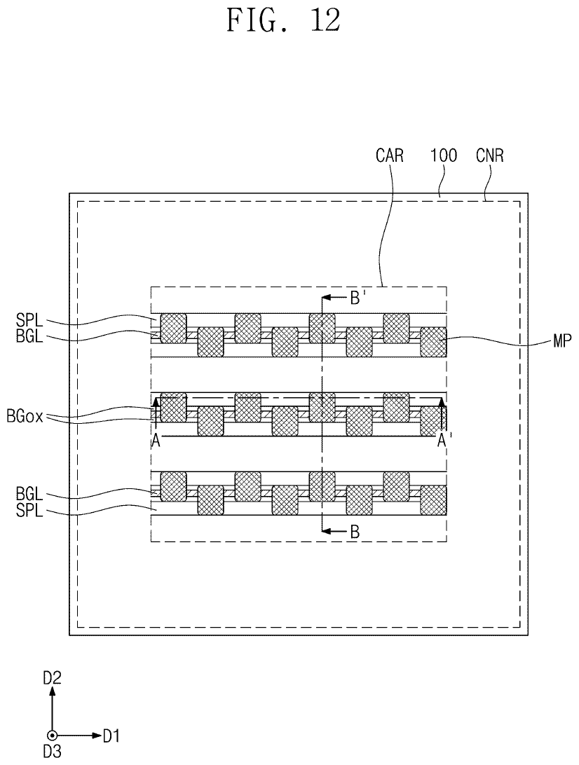

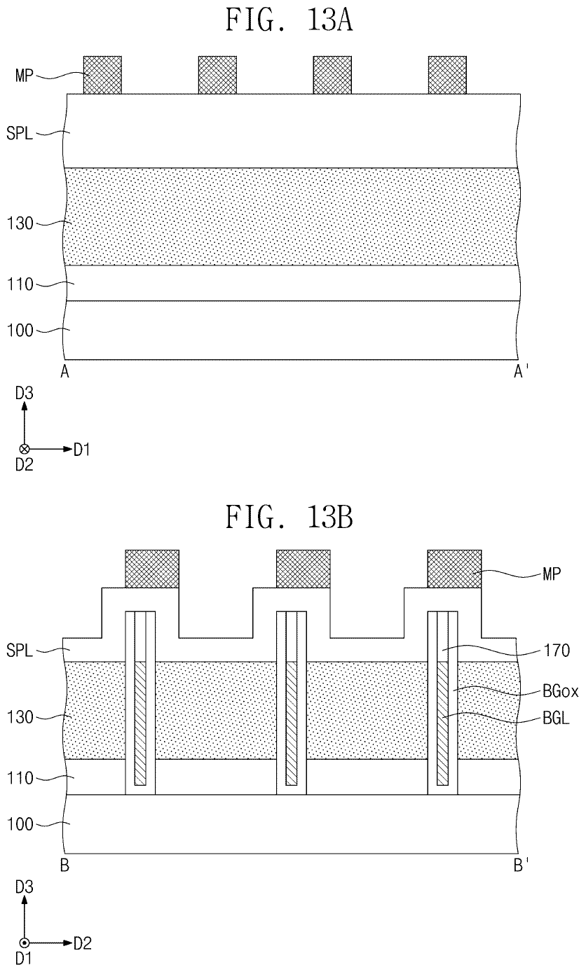

Referring to FIGS. 12, 13A, and 13B, the second preliminary insulating layer 150 may be removed. The second preliminary insulating layer 150 may include a material having an etching selectivity with respect to the back-gate insulating layers BGox and the back-gate capping layers 170. Accordingly, only the second preliminary insulating layer 150 may be selectively removed while the back-gate insulating layers BGox and the back-gate capping layers 170 remain. The semiconductor layer 130 may be exposed due to the second preliminary insulating layer 150 removed.

A spacer layer SPL having a uniform thickness may be formed on the semiconductor layer 130. The spacer layer SPL may cover the back-gate insulating layers BGox and the back-gate capping layers 170 on the semiconductor layer 130. Since the back-gate insulating layers BGox and the back-gate capping layers 170 protrude from a top surface of the semiconductor layer 130 in a third direction D3, the spacer layer SPL may have a step difference (or, height variation) in the third direction D3.

Mask patterns MP may be formed on the spacer layer SPL. Each of the mask patterns MP may partially overlap the back-gate lines BGL. The mask patterns MP may be spaced apart from one another in the first direction D1 and the second direction D2. That is, the mask patterns MP may be two-dimensionally arranged. For example, the mask patterns MP may be arranged in a shape of zigzag. In a plan view, each of the mask patterns MP may have a shape of rectangular, but is not limited thereto.

According to embodiments, the mask patterns MP may have a shape of line or bar extending in a diagonal direction with respect to the first direction D1 and the second direction D2. In this case, the mask patterns MP may be arranged in a similar shape to the bit lines BL described with reference to FIG. 8B.

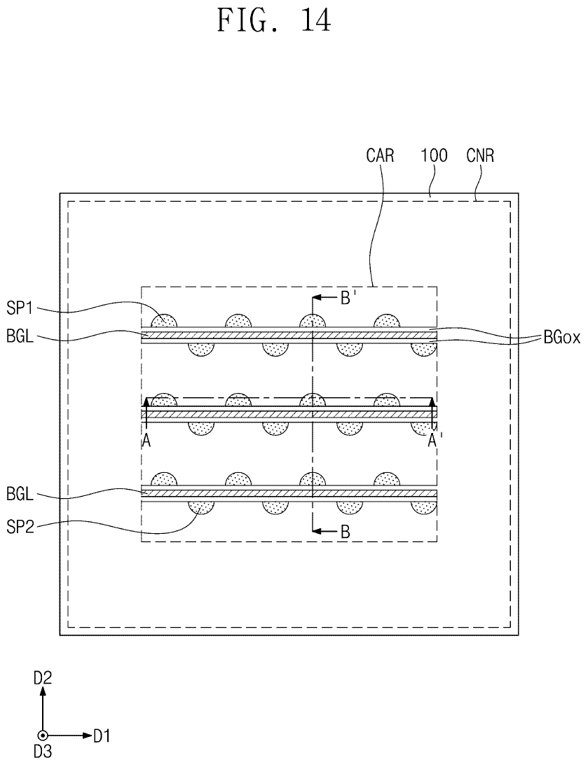

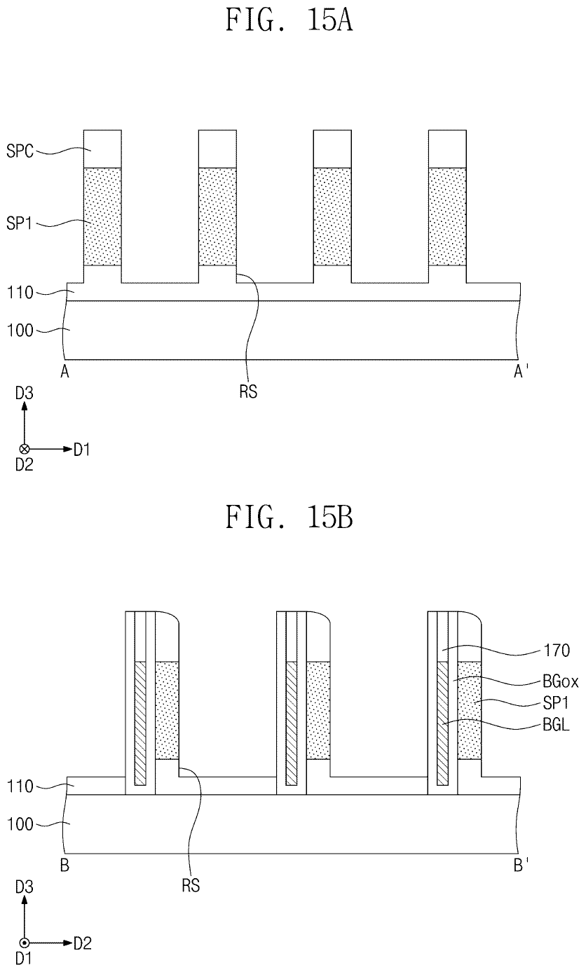

Referring to FIGS. 14, 15A, and 15B, an anisotropic etching process using the mask patterns MP as an etching mask may be performed. The anisotropic etching process may partially remove the spacer layer SPL. Accordingly, a portion of the spacer layer SPL vertically overlapping the mask patterns MP may remain and be formed of spacers SPC. In a plan view, the spacers SPC may be alternately positioned on both side surfaces of each of the back-gate lines BGL in the first direction D1. For example, the spacers SPC may be arranged in a shape of zigzag with respect to each of the back-gate lines BGL.

The mask patterns MP may be removed, and an etch-back process using the spacers SPC may be additionally performed. For example, the etch-back process may be an etching process performed on the top surface of the substrate 100. The semiconductor layer 130 and the first preliminary insulating layer 110 may be partially removed due to the etch-back process. For example, a portion of the semiconductor layer 130 that does not vertically overlap with the spacers SPC may be removed. Accordingly, the first semiconductor patterns SP1 and the second semiconductor patterns SP2 vertically overlapping the spacers SPC and extending in the third direction D3 may be formed. For example, edges of each of the spacers SPC may be removed together due to the etch-back process, so that each of the first semiconductor patterns SP1 and the second semiconductor patterns SP2 may have a planar shape of semicircular.

Due to the arrangement of the spacers SPC, the first semiconductor patterns SP1 and the second semiconductor patterns SP2 may be arranged in a shape of zigzag with respect to each of the back-gate lines BGL. The first semiconductor patterns SP1 and the second semiconductor patterns SP2 adjacent to one another may be offset in the first direction D1. Accordingly, a sufficient interval may be secured between the first semiconductor patterns SP1 and the second semiconductor patterns SP2 adjacent to one another. As described with reference to FIGS. 7A and 7B, a parasitic capacitance between the first gate lines GL1 and the second gate lines GL2 to be described later may be prevented or reduced.

Due to the etch-back process, the first preliminary insulating layer 110 may include recessed regions RS, in which upper portion of the first preliminary insulating layer 110 is recessed. A top surface of the first preliminary insulating layer 110 may be lowered due to the recess regions RS. The recess regions RS may not expose the top surface of the substrate 100, but are not limited thereto.

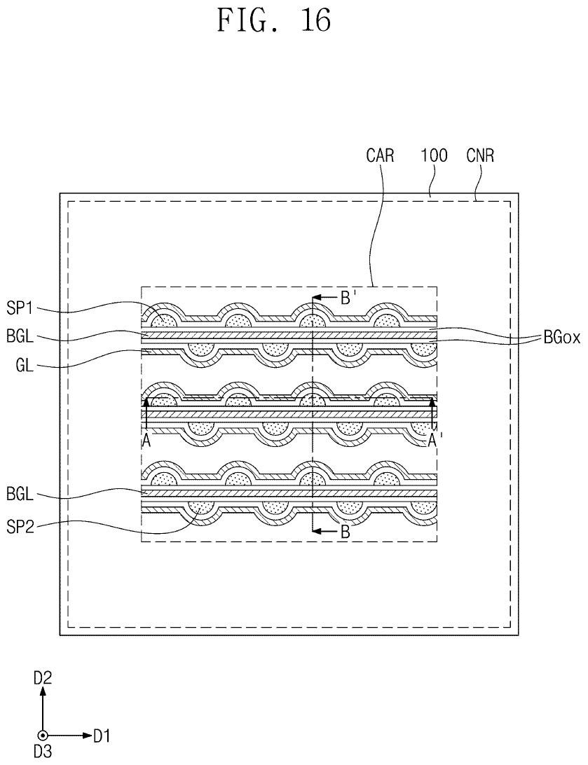

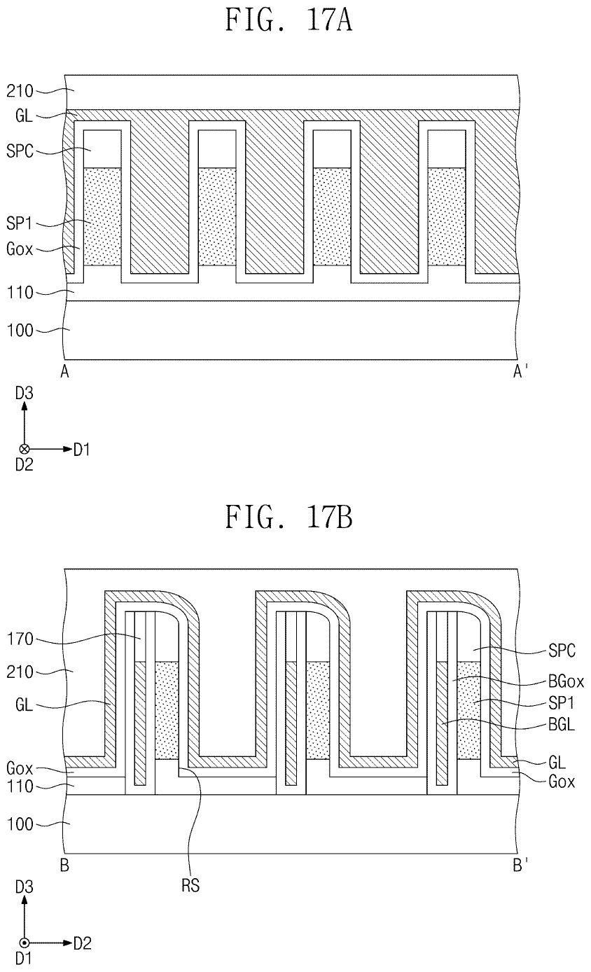

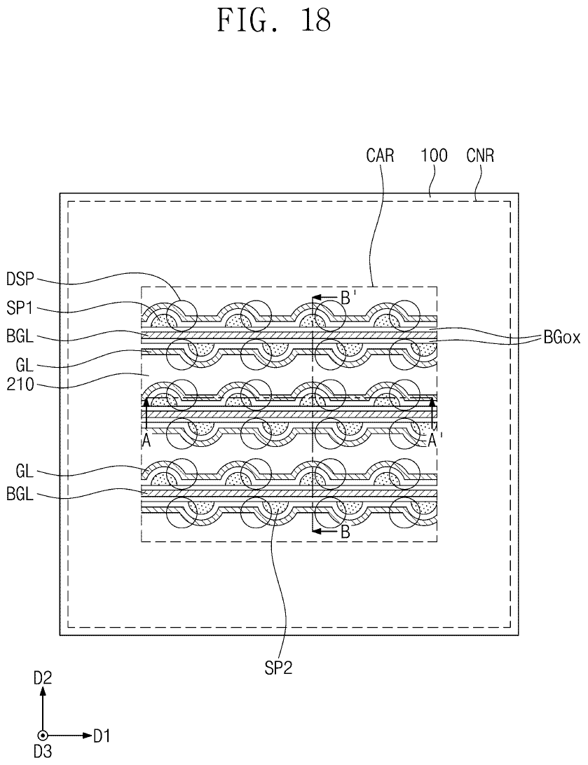

Referring to FIGS. 16, 17A, and 17B, a gate insulating layer Gox may be formed on the top surface of the substrate 100. The gate insulating layer Gox having a uniform thickness may extend in the recess regions RS of the first preliminary insulating layer 110 while covering the spacers SPC, the first semiconductor patterns SP1, and the second semiconductor patterns SP2. For example, the gate insulating layer Gox may be include silicon oxide, silicon oxynitride, silicon nitride, a high dielectric constant material, or a combination thereof.

A gate line GL may be formed on the gate insulating layer Gox. The gate line GL may cover the gate insulating layer Gox with a uniform thickness. Thus, a space may be formed between the back-gate lines BGL adjacent to one another in the second direction D2. For example, the gate line GL may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but is not limited thereto.

A capping insulating pattern 210 may be formed on the gate line GL. The capping insulating pattern 210 may fill the space between the back-gate lines BGL adjacent to one another in the second direction D2 while covering the gate line GL.

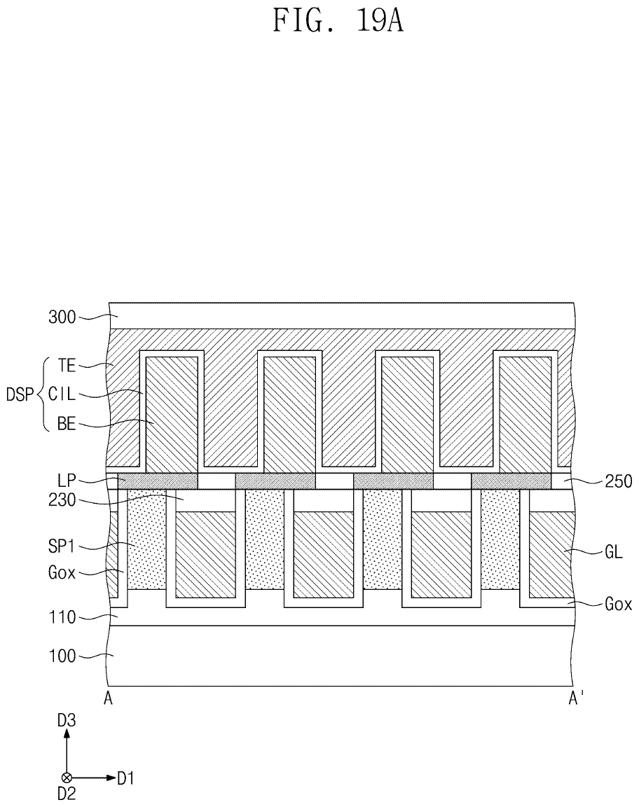

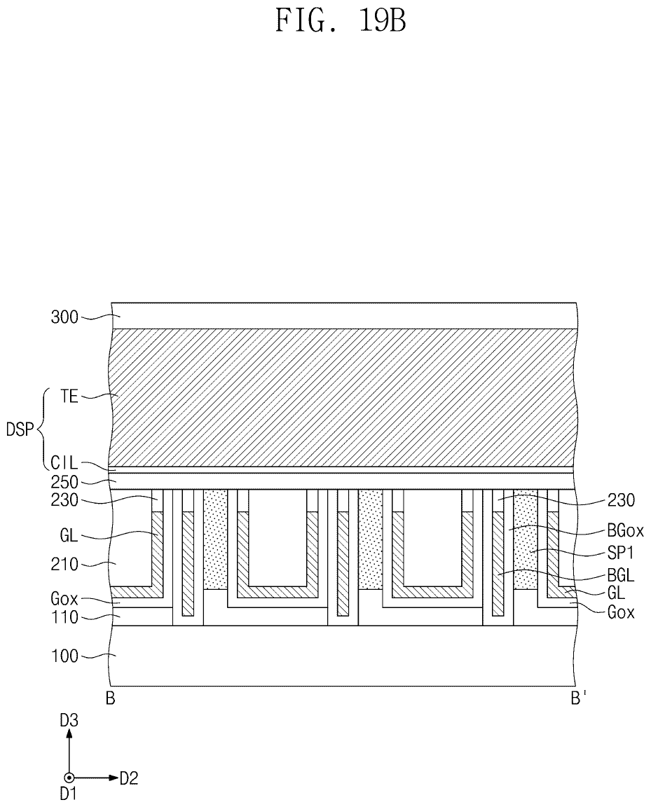

Referring to FIGS. 18, 19A, and 19B, a planarization process may be performed on the top surface of the substrate 100. For example, the planarization process may include an etch-back process and a chemical mechanical polishing (CMP) process. The planarization process may be performed until top surfaces of the first semiconductor patterns SP1 and the second semiconductor patterns SP2 are exposed. Accordingly, the back-gate lines BGL may also be exposed together. The capping insulating pattern 210 may be separated into a plurality of capping insulating patterns 210.

Thereafter, a metal etch-back process for the gate lines GL and the back-gate lines BGL may be performed. The metal etch-back process may selectively remove only back-gate lines BGL and gate lines GL that include the metal material. Accordingly, the capping insulating patterns 210, the first semiconductor patterns SP1, and the second semiconductor patterns SP2 may be remained. An upper portion of each of the back-gate lines BGL and the gate line GL may be recessed due to the metal etch-back process.

An upper buried layer 230 may be formed in the upper portion of each of the back-gate lines BGL and the gate line GL. The upper buried layer 230 may be located on the back-gate lines BGL and the gate line GL. The upper buried layer 230 may have a top surface positioned at the same level as top surfaces of the first semiconductor patterns SP1, the second semiconductor patterns SP2, and the capping insulating patterns 210.

An interlayer insulating layer 250 may be formed on the first semiconductor patterns SP1 and the second semiconductor patterns SP2. The interlayer insulating layer 250 may cover the first semiconductor patterns SP1, the second semiconductor patterns SP2, and the capping insulating patterns 210. The interlayer insulating layer 250 may be in contact with the upper buried layer 230, the back-gate insulating layers BGox, and the gate insulating layer Gox.

The interlayer insulating layer 250 may be patterned to form landing pads LP in the interlayer insulating layer 250. The landing pads LP may be in contact with the corresponding first semiconductor patterns SP1 and second semiconductor patterns SP2. Each of the landing pads LP may have a larger planar width (or, horizontal width) than that of the first semiconductor patterns SP1 and the second semiconductor patterns SP2. Accordingly, the landing pads LP may be partially in contact with the upper buried layer 230.

Data storage patterns DSP may be formed on the interlayer insulating layer 250 and the landing pads LP. Forming the data storage patterns DSP may include forming bottom electrodes BE, forming a capacitor dielectric layer CIL covering the bottom electrodes BE with a uniform thickness, and forming a top electrode TE covering the capacitor dielectric layer CIL.

Each of the bottom electrodes BE may extend from the interlayer insulating layer 250 in the third direction D3. The bottom electrodes BE may be spaced apart from one another in the first direction D1 and the second direction D2. The bottom electrodes BE may be connected to the corresponding first semiconductor patterns SP1 and second semiconductor patterns SP2 through the landing pads LP. In a plan view, the bottom electrodes BE may be arranged in a shape of matrix on the landing pads LP. Accordingly, the bottom electrodes BE may partially overlap the corresponding first semiconductor patterns SP1 and second semiconductor patterns SP2.

Thereafter, an upper insulating layer 300 may be formed on the data storage patterns DSP. The upper insulating layer 300 may cover the top electrode TE of the data storage patterns DSP.

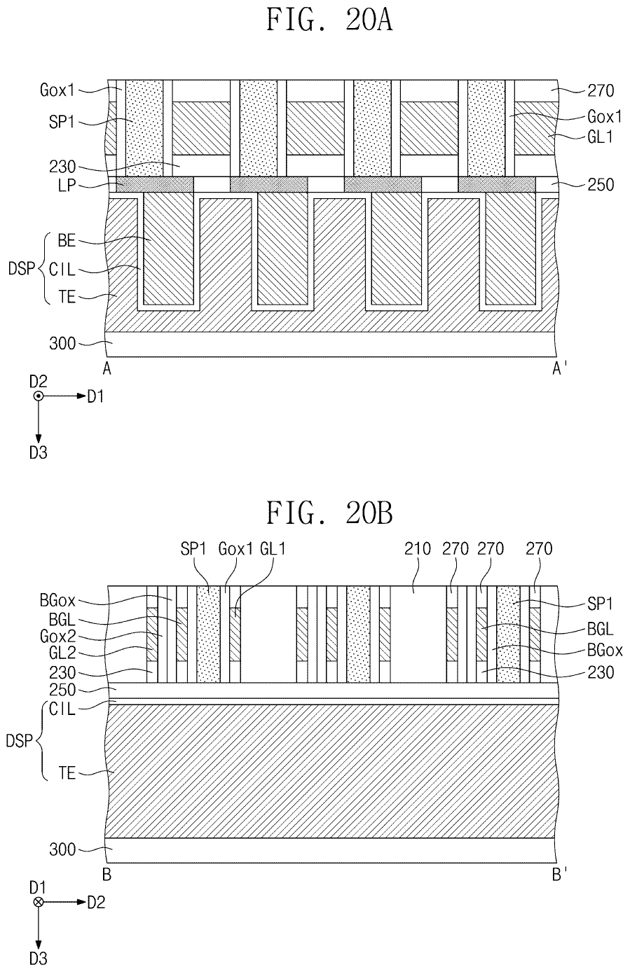

Referring to FIGS. 18, 20A, and 20B, the substrate 100 may be inverted. Accordingly, the upper insulating layer 300 may be positioned at a lower level than the substrate 100. In a state where the substrate 100 is turned upside down, a polishing process for the substrate 100 may be performed. The polishing process may proceed until the first semiconductor patterns SP1 and the second semiconductor patterns SP2 are exposed.

The polishing process may remove the substrate 100. The gate line GL and the gate insulating layer Gox may be partially removed and separated into a plurality of gate lines GL and gate insulating layers Gox by the polishing process. For example. first gate lines GL1 and second gate lines GL2 may be formed from the gate line GL. First gate insulating layers Gox1 and second gate insulating layers Gox2 may be formed from the gate insulating layer Gox.

Thereafter, a metal etch-back process may be performed on the back-gate lines BGL, the first gate lines GL1, and the second gate lines GL2. The metal etch-back process may selectively remove the back-gate lines BGL, the first gate lines GL1, and the second gate lines GL2 including the metal material. A lower portion (e.g., an upper portion when the substrate 100 is inverted) of each of the back-gate lines BGL, the first gate lines GL1, and the second gate lines GL2 may be recessed due to the metal etch-back process.

A lower buried layer 270 may be formed in the lower portion of each of the back-gate lines BGL, the first gate lines GL1, and the second gate lines GL2. The lower buried layer 270 may be positioned below each of the back-gate lines BGL, the first gate lines GL1, and the second gate lines GL2. The lower buried layer 270 may have a bottom surface (e.g., a top surface when the substrate 100 is inverted) positioned at the same level as bottom surfaces of the first semiconductor patterns SP1, the second semiconductor patterns SP2, and the capping insulating patterns 210.

Referring again to FIGS. 4, 5A, and 5C, bit lines BL may be formed when the substrate 100 is inverted. Forming the bit lines BL may include forming a bit line layer, forming a mask pattern on the bit line layer, patterning the bit line layer using the mask pattern as an etch mask, and removing the mask pattern. The bit lines BL may be formed in various shapes as described with reference to FIGS. 8A to 8C.

Thereafter, a lower insulating layer 400 covering the bit lines BL may be formed. The lower insulating layer 400 may cover the bit lines BL, the capping insulating patterns 210, and the lower buried layer 270.

According to embodiments, the semiconductor patterns may be offset in the first direction. Accordingly, a minimum interval between the gate lines may be increased, and a difference between the minimum interval and a maximum interval between the gate lines may be reduced. For example, the minimum interval and the maximum interval between the gate lines may be substantially the same. Thus, a parasitic capacitance between the gate lines and voids in the capping insulating pattern may be prevented or reduced. Therefore, electrical characteristics of the semiconductor memory device may be improved.

While embodiments are described above, a person skilled in the art may understand that many modifications and variations are made without departing from the spirit and scope of the disclosed concepts defined in the following claims. Accordingly, the example embodiments of the disclosed concepts should be considered in all respects as illustrative and not restrictive, with the spirit and scope of the disclosed concepts being indicated by the appended claims.

What is claimed is:

1. A semiconductor memory device comprising:
a lower insulating layer;
back-gate lines each extending in a first direction on the lower insulating layer;
first semiconductor patterns on first side surfaces of the back-gate lines; and
second semiconductor patterns on second side surfaces of the back-gate lines,
wherein the first semiconductor patterns and the second semiconductor patterns are alternately disposed along the first direction.

2. The semiconductor memory device of claim 1, wherein each of the second semiconductor patterns is between two adjacent first semiconductor patterns of the first semiconductor patterns in a plan view.

3. The semiconductor memory device of claim 1, wherein distances between each of the second semiconductor patterns and two adjacent first semiconductor patterns of the first semiconductor patterns are approximately same.

4. The semiconductor memory device of claim 1, wherein distances between each of the second semiconductor patterns and two adjacent first semiconductor patterns of the first semiconductor patterns are different.

5. The semiconductor memory device of claim 1, further comprising:
a first gate line on side surfaces of the first semiconductor patterns;
a second gate line on side surfaces of the second semiconductor patterns; and
a capping insulating pattern between the first gate line and the second gate line.

6. The semiconductor memory device of claim 5, wherein the first gate line and the second gate line are between the back-gate lines, and
wherein a distance between the first gate line and the second gate line is 10 nm to 20 nm.

7. The semiconductor memory device of claim 5, wherein the capping insulating pattern has a substantially uniform horizontal width.

8. The semiconductor memory device of claim 5, further comprising:
a back-gate insulating layer covering the first side surfaces and the second side surfaces of the back-gate lines;
a first gate insulating layer between the first semiconductor patterns and the first gate line; and
a second gate insulating layer between the second semiconductor patterns and the second gate line,
wherein the first gate insulating layer and the second gate insulating layer partially contact the back-gate insulating layer.

9. The semiconductor memory device of claim 1, further comprising:
bit lines in the lower insulating layer,
wherein the bit lines vertically overlap the first semiconductor patterns and the second semiconductor patterns.

10. The semiconductor memory device of claim 9, wherein each of the bit lines extends in a diagonal direction with respect to the first direction.

11. A semiconductor memory device comprising:
a lower insulating layer;
a back-gate line extending in a first direction on the lower insulating layer;
a first gate line on a first side surface of the back-gate line;
a second gate line on a second side surface of the back-gate line;
first semiconductor patterns between the back-gate line and the first gate line; and
second semiconductor patterns between the back-gate line and the second gate line,
wherein the first semiconductor patterns and the second semiconductor patterns are offset in the first direction.

12. The semiconductor memory device of claim 11, wherein each of the first semiconductor patterns and the second semiconductor patterns extends in a direction substantially perpendicular to a top surface of the lower insulating layer.

13. The semiconductor memory device of claim 11, wherein the first semiconductor patterns and the second semiconductor patterns are arranged in a shape of zigzag along the first direction in a plan view.

14. The semiconductor memory device of claim 11, further comprising:
data storage patterns on the first semiconductor patterns and the second semiconductor patterns,
wherein, in a plan view, the data storage patterns partially overlap the first semiconductor patterns and the second semiconductor patterns, respectively.

15. The semiconductor memory device of claim 11, further comprising:
a back-gate insulating layer on the first side surface and the second side surface of the back-gate line;
a first gate insulating layer between the first gate line and the first semiconductor patterns; and
a second gate insulating layer between the second gate line and the second semiconductor patterns,
wherein the back-gate insulating layer partially contacts the first gate insulating layer and the second gate insulating layer.

16. The semiconductor memory device of claim 11, wherein each of the first semiconductor patterns and the second semiconductor patterns has a planar shape of semicircular.

17. A semiconductor memory device comprising:
a peripheral circuit structure including peripheral circuits on a substrate; and
a cell structure electrically connected to the peripheral circuit structure,
wherein the cell structure comprises:
a lower insulating layer;
bit lines in the lower insulating layer;
a back-gate line extending in a first direction on the lower insulating layer;
a first gate line and a second gate line spaced apart from one another with the back-gate line therebetween;
first semiconductor patterns between the back-gate line and the first gate line;
second semiconductor patterns between the back-gate line and the second gate line; and
data storage patterns on the first semiconductor patterns and the second semiconductor patterns,
wherein the first semiconductor patterns and the second semiconductor patterns are arranged in a shape of zigzag in a plan view.

18. The semiconductor memory device of claim 17, wherein the data storage patterns are arranged in a shape of matrix in a plan view, and
wherein the data storage patterns partially overlap the first semiconductor patterns and the second semiconductor patterns, respectively.

19. The semiconductor memory device of claim 17, wherein the first semiconductor patterns are spaced apart from one another in the first direction,
wherein the second semiconductor patterns are spaced apart from one another in the first direction, and
wherein the first semiconductor patterns and the second semiconductor patterns are offset in the first direction.

20. The semiconductor memory device of claim 17, wherein the back-gate line comprises a first back-gate line and a second back-gate line adjacent to one another, and
wherein a distance between the first gate line and the second gate line, which are between the first back-gate line and the second back-gate line, is substantially constant.
